(19) United States
(12) Patent Application Publication
(10) Pub. No.: US 2019/0004477 A1
(43) Pub. Date: Jan. 3, 2019

(54) OPTICAL DEVICES FOR AUTHENTICATION AND METHODS OF MAKING SAME

(71) Applicant: DUBLIN INSTITUTE OF TECHNOLOGY, Dublin (IE)

(72) Inventors: Izabela NAYDENOVA, Dublin (IE); Monika ZAWADZKA, Monkstown (IE); Suzanne MARTIN, Blanchardstown (IE); Dervil CODY, Dublin (IE); Vincent TOAL, Co. Dublin (IE); Tatsiana MIKULCHYK, Dublin (IE)

(21) Appl. No.: 16/063,237

(22) PCT Filed: Dec. 21, 2016
(86) PCT No.: PCT/EP2016/082239

§ 371 Date: Jun. 15, 2018

(30) Foreign Application Priority Data
Dec. 23, 2015 (GB) 1522833.1
May 23, 2016 (GB) 1608987.2

(51) Int. Cl. G03H 1/20; G03F 7/00; G03F 7/20; G03H 1/02; G03H 1/04; G03H 1/16; G03H 1/18; G03H 1/26

(52) U.S. Cl. CPC G03H 1/20; G03F 7/001; G03F 7/2002; G03H 1/0248; G03H 1/0404; G03H 2260/12; G03H 1/182; G03H 1/2645; G03H 2001/0292; G03H 2001/207; G03H 2250/42; G03H 1/16

(57) ABSTRACT

The invention optical device comprising a self-processing photopolymer material configured to produce a variable two- or three- dimensional diffraction pattern when said material is illuminated by a light source. The invention provides a new material science and process technology which produces a serialisable anti-counterfeit optical device, based on a self-processing photopolymer.

### FIELD

The invention relates to Optical devices for authentication and methods for their fabrication.

### BACKGROUND

Optical security features of various types are now commonplace on bank and credit to cards and are increasingly present on many types of documents, tickets banknotes and consumer products. Depending on their functionality and role at the verification process there are three main types of optical devices that used in security —overt, semi covert and covert features. Overt features are usually defined as those that are readily visible to the authenticating party and are designed to be easily detectable by eye under normal daylight or normal lighting. Typical examples are holograms and colour-shifting inks as well as security threads. Semi-covert features require prior knowledge and action on the part of the person checking the feature. They may be hidden in the documents design and or need simple equipment to verify them. Examples include thermochromic inks, fluorescent fibres and hidden text. Covert/forensic features require very specific knowledge and/or equipment to read and information on them is not usually disseminated to the consumer.

Diffractive and holographic features are possibly the most well recognised optical security features. The advantage of adding them is the difficulty involved in replicating them. They can therefore act as deterrents to forgers, provide authentication features for consumers and can help producers discover where and when fraud is occurring.

The method most commonly used in applying diffractive or holographic security features is a hot stamping process. The result is a transparent layer with sub-micron surface relief structure, backed by a reflective layer that allows the light diffracted form the structure to be view in reflection.

It is also possible to apply a transparent coating for viewing in transmission, but the material must have a substantially different refractive index to the surface relief material, or the effect will be lost. The structure can of course be left uncovered, but it would be vulnerable to moisture, dust and other contaminants. For Passport or identity cards, where lamination with another plastic (similar refractive index) is desirable the surface relief method is not suitable.

It is desirable to produce low cost individualised labels or devices that can be used as to covert security features in different commercial products. One method is a standard surface relief method for production of security devices and is not suitable in passport or identity cards, where lamination with another plastic (similar refractive index) is desirable.

Recent patent publications, such as U.S. Pat. No. 7,871,741, have addressed this problem by ablating an ‘opacifying’ layer applied to the transparent substrate. Using this method diffractive microstructures or Diffractive Optical Elements (DOEs) are formed. Since the diffracting structure in that case was a pattern of opaque and clear regions rather than a surface relief, lamination did not pose a problem and it was stated that the feature could be incorporated into identity cards and other laminated products. This approach was used to produce security features of the type that diffract light. The ablated patterns are calculated to diffract incident light to form a two dimensional pattern in the far field, for example on a wall.

However, such opaque features would be likely to produce high loss and scatter since in a typical diffraction pattern approximately 50% of the surface has been made opaque at the reconstruction wavelength by the laser treatment. In addition, the wavelengths needed for ablation are in the UV range (e.g 248 nm) and the process therefore involves the use of relatively expensive laser equipment. Other approaches include printing an embossable transparent resin, printed in the desired shape/text and then embossed with a diffraction pattern, for example as disclosed in GB2,482,077.

French patent publication number FR2975945 discloses another method for the production of diffractive features in transparent window involved laser ablation and taught partial removal of metallic or not metallic features, including diffractive features or holograms in order to incorporate variable data such as biodata into passports and documents. In this case direct writing of the diffractive features was not proposed, rather the removal of unwanted material in order to shape existing features into text or images.

In other cases diffractive elements are mass produced for other applications using to illumination through appropriate masks and photosensitive polymers, as disclosed in US 2009 00091833.

Previous inventions taught methods for the use of fully transparent photopolymerizable polymer for the selective printing of holograms in the shape of logos, text and other variable data, using the application of sensitizing dye by inkjet and other printing processes, as shown in U.S. Pat. No. 8,383,294.

International Patent Publication No. WO2008/045625 describes a method for providing product authentication. In one embodiment of this method, the authentication is provided by including a moulded feature on a product, the feature being made from a photopolymerisable material in which a volume hologram may be recorded. In an alternative embodiment of the method, the mould may be coated with a photopolymer, and a hologram recorded in the photopolymer.

In both embodiments of the described method, the hologram is recorded by a split beam method. This involves splitting a laser beam into two beams by a beamsplitter. It will be appreciated that such a recording method requires extreme mechanical and thermal stability over the whole of the recording area, which area is the substantially square space encompassed by the beamsplitter, a mirror, a spatial light modulator and the recording plane where the photopolymer is located. As a result, it has been found that such a recording arrangement is very difficult to implement for mass-manufacturing purposes.

It is therefore an object to provide an improved optical device for authentication and methods of making same.

### SUMMARY

According to the invention there is provided an optical device comprising a photopolymer material.

The present invention improves on the state-of-the art methods by using visible-wavelength light and a fully transparent (once exposed) photopolymerizable polymer to produce diffractive optical elements that produce a variable two- or three-dimensional diffraction pattern. The devices have the advantage of being fully transparent rather than having opaque sections, produced with visible rather than UV light and are suitable for the production of DOEs that produce variable data such as images and biodata. These mass producible individualisable optical devices are possible due to the use of a highly sensitive, self-processing photopolymer.

Furthermore, it should be noted that the present invention may use a single beam of visible laser light to illuminate a SLM (Spatial light modulator) onto which a pattern has been written. The light transmitted or reflected by the SLM consists of zero order directly transmitted or reflected light accompanied by light which is diffracted by the SLM and carrying the information to be written to the optical device. This information can for example be a Fourier transform of the image that will ultimately be displayed.

This light passes through a lens, and a hologram is recorded in the image plane of the lens. Such recording requires a photopolymer sensitive to the spatial frequencies, ranging right down to almost zero, that are associated with Gabor holography. One advantage resulting from such a recording method is that the mechanical and thermal stability requirements are far less stringent than methods which require double beam exposure to record a pattern. This is due to the fact that any disturbances during a recording affect the zero order and the diffracted light to much the same extent and in the same way, so that the interference pattern to be recorded in the photopolymer is quite constant during the recording time. In addition, the reconstruction and illuminating beam are collinear, rather than at an inconvenient angle, as is the case in respect of double beam recording methods.

As a result of this reduced requirement for thermal and mechanical stability during the recording process of the present invention, the optical device of the present invention facilitates mass production in an industrial environment.

According to a first aspect of the invention, there is provided, as set out in the appended claims, a fully transparent optical device comprising a self-processing photopolymer material patterned to diffract light from the volume of the material to generate a 2D or a 3D image when illuminated by a light source, wherein the optical device is patterned by using a single laser beam.

The device may be patterned by an in-line holographic recording of a spatially transformed wavefront.

The photopolymer material may comprise N-phenylglycine, NPG, glycerol, triethanolamine (TEA), polyvinylalcohol (PVA) and one or more of the monomers N-isopropylacrylamide, acrylamide or diacetone acrylamide.

The device may be a reflection type of device.

The device may comprise a reflective surface placed behind a transmission type of device, wherein the reflective surface is in direct contact with the photopolymer material.

The roughness of the reflective surface may be of the order of 0.010 micrometres.

The reflective surface may comprise aluminium reflective foil.

The device may be a transmission type of device or a reflection volume hologram device.

The photopolymer material may be configured by the recording of a pattern onto the photopolymer material comprising the image or a computer generated hologram of the image to be generated by the device.

The computer generated hologram may comprise the Fourier transform of the image to be generated by the device.

The pattern may be recorded by projecting light through the pattern onto the photopolymer material and the photopolymer material is sensitized to the wavelength of the light and fully or partially polymerised to form a refractive index variation in the volume of the photopolymer material.

A single laser beam which is spatially modulated in amplitude and/or phase may encrypt the recorded pattern.

The pattern to be recorded onto the photopolymer material may be displayed on a spatial light modulator, SLM, or incorporated into a mask or by digitally printing an ink comprising a sensitiser on the unsensitised photopolymer material.

The SLM may be divided into one part for displaying the pattern of first laser beam and another part for displaying the pattern of the second laser beam.

The mask may be placed in direct contact with the photopolymer material.

The laser may have a wavelength in the range of the visible light spectrum to the infra-red spectrum.

The laser may comprise a collimated laser beam.

The image generated by the device may be reflected by at least one mirror prior to read-out.

The image generated by the device may be readable by a CCD or CMOS camera.

The photopolymer material may comprise multiple layers.

The image may comprise one of: a logo or a customized code.

In a second aspect of the invention there is provided a method of producing a diffractive optical element, DOE, from an optical device comprising a photopolymer material, the method comprising:

optically recording a pattern in the photopolymer material by projecting a single beam of laser light through the pattern onto the photopolymer material so as to cause a refractive index variation in the volume of the photopolymer material, wherein the material is fully or partially polymerised at the end of the optical recording.

The light may have a wavelength in the range of the visible light spectrum to the infra-red spectrum.

The step of projecting light through the pattern may comprise projecting light through a pattern displayed on an SLM.

The step of projecting light through the pattern may comprise projecting light through a pattern on a physical mask.

The mask may be provided in direct contact with the photopolymer material.

The method may further comprise digitally printing a computer generated pattern using ink comprising a sensitizer on the unsensitised photopolymer material prior to recording.

The method may further comprise heating the optical device to a temperature in the range 100 to 140 degrees Celcius for a period greater than 60 minutes to fully polymerize and/or improve the characteristics of the device.

The method may further comprise exposing the optical device to ultra violet, UV, light.

The photopolymer material may comprise N-phenylglycine, NPG, glycerol, triethanolamine, TEA, polyvinylalcohol, PVA and one or more of the monomers N-isopropylacrylamide, acrylamide or diacetone acrylamide. The method may further comprise recording the pattern at 0.4 mW/cm² for 20 to 30 seconds and wherein the thickness of the photopolymer material is 50 μm.

The thickness of the photopolymer material may be between 20-150 μm and the recording intensity and the time of recording may be in the range 0.4-2 mW/cm² and 10-80 s respectively

The thickness of the photopolymer material may be 75 μm and the method may further comprise recording the pattern at 1 mW/cm² for 20 seconds.

In a further embodiment of the invention there is provided an optical device comprising a plurality of DOEs, wherein each DOE is distributed in a predefined manner.

In a further embodiment of the invention there is provided an optical device comprising a plurality of DOEs, wherein each DOE is multiplexed in the same location.

In a further embodiment of the invention there is provided an optical device for use in one of: authentication, beam shaping, machine vision or visual display applications.

In a further embodiment of the invention there is provided a method of generating an image from a diffractive optical element, DOE comprising:

illuminating the DOE with laser light so as to generate an image produced by the pattern recorded in the photopolymer material of the DOE.

The light may have a wavelength in the range of the visible light spectrum to the infra-red spectrum.

The method may further comprise reflecting the generated image from at least one mirror prior to read out.

The method may further comprise detecting the generated image in a charge coupled device, CCD, or CMOS camera.

In one embodiment there is provided digital printing and illumination through an SLM for fabrication of the photopolymer optical devices.

In one embodiment the photopolymer material is chemically modified.

In one embodiment there is provided a Raman spectroscopic methodology used to determine the concentration of monomer remaining in the photopolymer after holographic recording of optical devices. In one embodiment the invention identifies the optimum conditions to obtain full polymerisation of the optical devices via thermal and UV exposure.

In one embodiment there is provided use of spatial light modulator to modulate a laser beam and input serialised alphanumeric characters to be optically recorded in holographic form as raw data or as a spatial Fourier transform.

In one embodiment there is provided partitioning of SLM to enable both object and reference beams for off axis holography. Also involved in the development of printing photosensitising ink on photopolymer for spatially modulated photosensitivity and photopolymerisation.

In one embodiment the composition contains the monomer N-isopropylacrylamide as replacement for acrylamide, the electron donor N-phenylglycine (NPG) as substitute for Triethanolamine (TEA), and the plasticizer glycerol.

In another embodiment of the invention there is provided an optical device comprising a self-processing photopolymer material patterned to diffract light from the volume of the material to generate a 2D or a 3D image when illuminated by a light source, wherein the optical device is fully transparent.

The light source may comprise at least one laser having a wavelength in the range of the visible light spectrum to the infra-red spectrum.

A laser beam which is spatially modulated in amplitude and/or phase may encrypt the recorded pattern.

In another embodiment of the invention there is provided a method of producing a diffractive optical element, DOE, from an optical device comprising a photopolymer material, the method comprising:

optically recording a pattern in the photopolymer material by projecting laser light through the pattern onto the photopolymer material so as to cause a refractive index variation in the volume of the photopolymer material, wherein the material is fully or partially polymerised at the end of the optical recording

### BRIEF DESCRIPTION OF THE DRAWINGS

The invention will be more clearly understood from the following description of an embodiment thereof, given by way of example only, with reference to the accompanying drawings, in which:

FIG. 1 Optical device a) and a pattern produced after illumination with a single beam of light b).

FIG. 2 illustrates a number of fabrication methods

FIG. 3. SLM recoding set-up.

FIG. 4.a) Contact masking device recording set-up b) non-contact masking recording set-up.

FIG. 5. Light pattern generated by a device which phase pattern what computed with a) Holoeye software as 8-bit greyscale pattern b) Holoeye and then manually converted into a binary pattern at the threshold of 128 c) VirtualLab (developed by LightTrans International UG) as a binary pattern.

FIG. 6a. % AA monomer remaining after different post-exposure techniques.

FIG. 6b shows a table of diffraction efficiency (DE) recalculated as ratio of the intensity of the first order and the incident intensity. Losses ((PI-Pt)/PI where PI is the power of the incident light and Pt is the power of the zero and first order transmitted light) versus energy density of the recording for various thickness of photopolymer films (d1=25,d2=50,d3=75,d4=100,d5=125 and d6=150). Lines are guide to eye only.

FIG. 7. Image of the light pattern generated with light beam with the diameter of a) 1 b) 3 and c) 5 mm.

FIG. 8. Scheme of the read-out devices for a) reflection and b) tranmission type of the devices.

FIG. 9. The images of light pattern generated with laser pointers with varied wavelength.

FIG. 10 Read-out using Fourier set-up.

FIG. 11a) pattern A recorded as off-axis hologram b) pattern B recorded as off-axis hologram c) light pattern generated by combining in space light patterns from A and B devices.

### DETAILED DESCRIPTION OF THE DRAWINGS

The invention provides a new material science and process technology which produces a serialisable anti-counterfeit optical device, based on a self-processing photopolymer.

The devices are practically invisible in room lighting, but produce a very specific pattern of light beams when illuminated by a single beam of light. The exact spatial positions of the emerging beams can be captured by a CCD camera. Thus the output of the proposed diffractive optical device is machine readable and this makes the device suitable as a covert security feature that can be added to a package/label, and which can be checked by a hand held reader or on a production line. The size of the device is on the order of a few millimetres which is an important feature for application as a security device. An example of the device and of the light pattern generated by a device upon its illumination with laser pointer is presented in FIG. 1.

The devices of the present invention provide the capability to produce low cost individualised labels or devices that can be used as covert security features in different commercial products.

In one embodiment the devices can take the form of a transmission or reflection device. For the former type, the desired light pattern is formed once light passes through the device hence this kind of devices can only be used on transparent packaging or goods.

To provide proper functioning of the device, the material of the packaging or good must not introduce random scattering of the probing beam. For the latter type of the devices the light pattern is formed, not behind the device as in transmission type of device, but in front of the device; therefore the device of such type can be attached as a label to the surface of the product.

Two methods of implementations of the reflection type of device are proposed. In the first one, a reflective surface placed behind a transmission type of the device. The other implementation of the reflection type of device takes form of reflective volume computer generated hologram, the fabrication of which was described in literature before (ref Vol. 17, No. 16 /APPLIED OPTIC). In such a case a hologram acts itself as a mirror. Yet, the read-out of such devices is highly dependent on the angle of the probing beam, which makes such devices less attractive candidates, in comparison to the previous devices, for the applications where quick and easy read-out is needed.

### Device Embodiment

A covert optical device of the invention may take the form of a spatial Fourier Transform of the input image. When the recorded transform is illuminated by means of a laser, the original image is displayed in the far field or in the Fourier plane of a lens behind the device. The first type is preferred since no need to additional optical elements are required in order to read out the information.

One can also encrypt the recorded Fourier Transform by using a reference beam which is spatially modulated in amplitude or phase or both. The image can only be displayed in the far field using a reference beam that replicates the original reference beam in amplitude and phase.

These devices are normally recorded as Gabor holograms which means that the output includes the image and its conjugate. The use of off-axis holography enables them to be spatially separated. One way of doing this is to divide a transmissive spatial light modulator (SLM) into two parts, left and right, and assign to one part the encoding of the reference beam and to the other the encoding of the Fourier Transform beam. In order for the beams to overlap at the recording plane, one of the beams (usually the reference) must also have a linear phase variation applied to it so that it is redirected by the correct angle. Suppose the SLM is square with side d. If a linear phase variation ranging from 0 to a maximum of O is applied to the beam passing normally through one half of the SLM, the beam will be steered through an angle of approximately:

O×wavelength/Pi×d

and the beams will overlap fully at a distance D from the SLM given by

D=d2×Pi/(2O×wavelength)

but there is little benefit to be obtained as D is typically several tens of metres. This is because the spatial resolution of the SLM and the total number of pixels allow only very small steering angles and the overlapping beams are therefore practically collinear.

However a pure phase, SLM usually of the Liquid Crystal on Silicon (LCOS) type could be used instead to make a reflective, Denysiuk device. A transmission SLM may be included to encrypt the reference beam if desired and the spatial Fourier Transform of the desired output image is written onto the LCOS SLM. The recorded device is illuminated by the reference beam and the image is seen in far field reflection.

The zero order and the two diffracted first orders can also be separated in space by imposing a phase shift during the generation of the computer hologram as demonstrated with the HoloEye software.

### Fabrication of the Devices

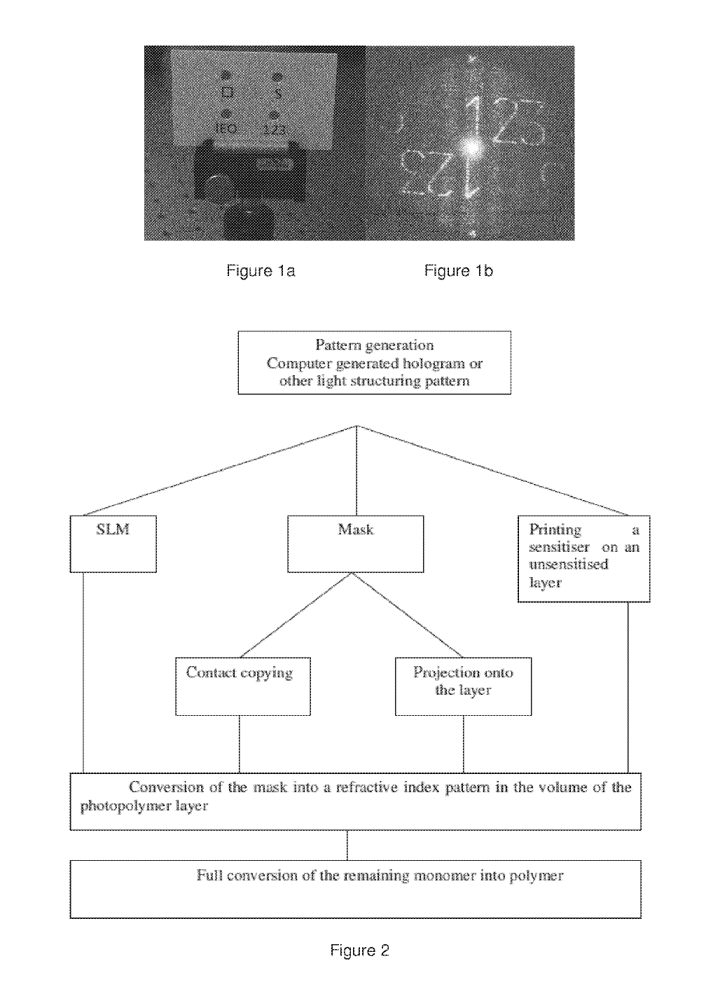

An important feature of the proposed devices is an ease of their individualisation. The image projected by the device when illuminated with a collimated light source can easily be changed from device to device. This is achieved by use of a computer controlled process of generation of the patterns used for device production. The fabrication of the device involves projecting the light through pattern displayed on the SLM or printed on transparency onto the photosensitive material and recording the projected pattern in the material as a change in refractive index. Alternatively the pattern can be printed on the unsensitised layer and exposed to light in order to induce local polymerisation. A brief summary of the proposed methods of device fabrication is given in FIG. 2

### SLM

In one embodiment device fabrication involves use of a spatial light modulator SLM of either transmission or reflection type. The pattern being projected on the SLM which is controlled by a computer, is recorded in photosensitive material when light passing through the SLM or reflected by it, is projected onto the recording material.

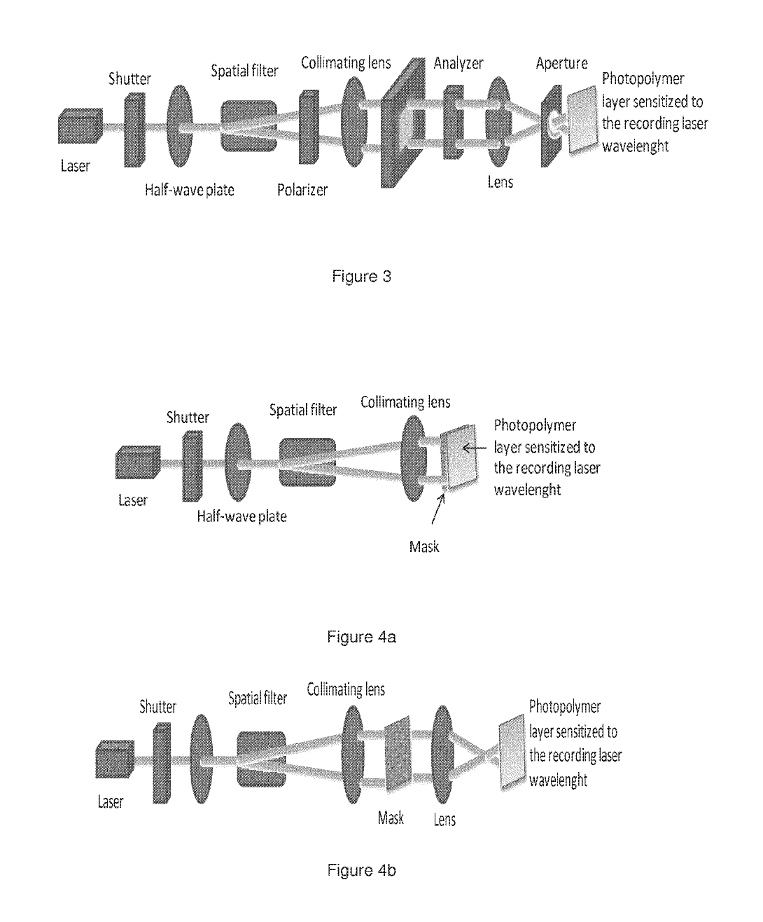

A simplified SLM recording set up is presented in FIG. 3. The recording of the devices with SLM can be carried with or with no aperture in the focal plane (FIG. 3). The role of the aperture is to filter the most intense zero diffraction (coming from SLM acting as a diffraction grating). Shall the projected light pattern contain only image (and its conjugate) the size of the aperture has to be adjusted for each of the pattern.

Otherwise, if no aperture is used, the projected light pattern comprises multiply images of the initial input. By adjusting the distance between the lens focal plane and the sample, one can induce changes to the spatial frequency of the device and hence to the size of the light pattern generated by the device.

### Masks

The other possibility of device fabrication is use of masks produced on transparencies either in contact copying or not contact copying of the mask by projecting it on the photopolymer layer. Such masks can be produced using advanced printing technologies (e.g. computer to film CtF technology allows production of high resolution patterns˜3600 dpi at low cost). The set-ups for device fabrication with contact and not contact masking are presented in FIG. 4. Although non-contact masking techniques requires more advanced recording set-up, it enables to overcome limitation of mask resolution since the image projected through the mask is demagnified on the photosensitive material.

### Printing

Another method of fabrication of the devices is through digital printing of the computer generated mask, being the Fourier Transform of the image to be projected by the optical device, on an unsensitised photopolymer layer. After allowing for the printed sensitiser to diffuse in the volume of the photopolymer layer the printed structure is illuminated by light of appropriate wavelength. Thus due to photopolymerisation in the sensitised regions the pattern is converted into a refractive index variation, capable of diffracting light in a manner reconstructing the original image.

The fabrication techniques described above are an illustration of simplest implementation of the recording set-ups with a single laser beam. Two-beam systems are necessary to record more complex devices, which read-out necessities the use the beam identical with the reference recording beam.

It will be appreciated that the quality of the light pattern generated by the device upon illumination with laser light depends on factors like:

1) quality of the pattern to be recorded/printed

2) formulation of the material and

3) the experimental condition of device production specific for the technology applied.

The device fabrication procedure has to be adjusted according to the desired type (i.e. transmission or reflection of the two types) of the device and its read-out beam characteristics (i.e. in simplest scenario read-out with collimated beam, in more complex read-out with the beam modified in phase or amplitude, replicating the recording reference beam).

1. Quality of the Pattern to be Recorded/Printed

The pattern to be recorded/printed, being the Fourier Transform of the image to be projected by the device, can be computed using programs like Virtual Lab, Holoeye application software, Cortical Café freeware software or others, as binary or greyscale light phase patterns using an iterative Fourier Transform Algorithm (IFTA). Further modification of the pattern to obtain the desired output image can be carried out. The simplest example involves introducing of a prism phase shift to the Fourier Transform to separate spatially the image from its conjugate. Others can involve e.g. superimposing lens effects or distortion of proportions of the computer generated pattern (the latter enables to prevent distortion of the projected image in the reflective type of device). The patterns can also be computed using other than IFTA algorithms which are being developed.

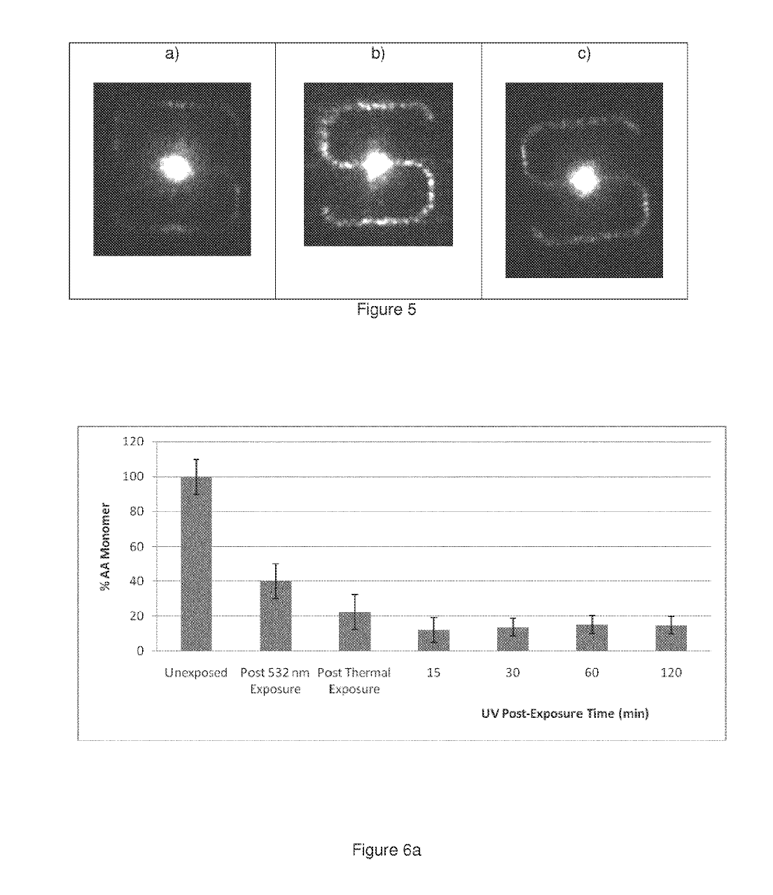

The comparison of the light patterns generated by a devices (recorded using photopolymer AA with SLM), which phase patterns were computed with Holoeye application software and VirtualLab as greyscale patterns are presented in FIG. 5a) and b) respectively. FIG. 5c) shows a photograph of the light pattern generated using a binary phase device computed with VirtualTrans. It will be appreciated that the use of greyscale over a binary mask may provide better quality reconstructed image input.

2) Formulation of the Material

An important aspect of the photopolymer composition is that the chemical composition can be modified to enhance optical device parameters such as diffraction efficiency, mechanical stability and visibility. These enhancements can be achieved in a number of ways, including replacement of different components such as the monomer, the addition of plasticizers or nanoparticle dopants.

A photopolymer formulation containing the monomer diacetone acrylamide and the plasticizer glycerol has been used to record optical devices in the form of gratings. This formulation achieves diffraction efficiencies of 50% for a recording intensity of 0.25 mW/cm² and exposure time of 50 seconds in 55±5 μm thick samples. This is higher than the 30-35% diffraction efficiency achieved with the standard acrylamide formulation for the same conditions. The modified composition is also capable of recording more complex optical devices.

A photopolymer formulation has been tested containing the monomer N-isopropylacrylamide as replacement for acrylamide, the electron donor N-phenylglycine (NPG) as substitute for Triethanolamine (TEA), and the plasticizer glycerol. Optical devices in the form of gratings were recorded using this formulation. Diffraction efficiencies of 58-59% were achieved for a recording intensity of 2 mW/cm² and exposure times of 30-50 seconds. This formulation also enables the optical device to be recorded at low spatial frequencies. The modified composition is also capable of recording more complex optical devices, and demonstrates enhanced mechanical stability. In addition, the monomer N-isopropylacrylamide (NIPA) could also be used to add an additional level of security to the optical device if desired, in the form of a thermal response. This is due to the fact that NIPA material is temperature sensitive.

The compositions described above were demonstrated to be excellent materials for transmission or reflection volume hologram devices. Yet, as far reflection type of devices of the other type of devices are considered, there are certain additional requirements on the material properties arising from the proposed design of the device, which is discussed below.

To ensure good performance of such device, the distance between the device and the reflective surface has to be minimised. The other factor which influences the performance of the device is the index matching between the reflective surface and the device.

In order to minimise the distance between the device and the reflective foil, it is proposed to put the photopolymer in direct contact with the reflective surface. Chemically resistant reflective foil must be used if the photopolymer material can interact chemically with the foil. For example, the use of acrylamide or diacetone acrylamide based compositions discussed above which contains TEA cannot be used with aluminium reflective foil. The application of these materials, in reflection type of devices, has also another disadvantage (if used with chemically resistant foils). The use of acrylamide based formula to record the devices, necessities the use of laminated films. Lamination prevents formation of surface relief profile which deteriorates the functioning of the device. To minimise the distance between the recorded device, the laminate would have to be removed, which process imposes technical difficulties. The use of the release liner is then necessary.

To overcome the problem mentioned above, another photopolymer acrylamide-based formulation with N-phenylglycine used instead of TEA, and with added glycerol is proposed for applications with aluminium reflective foils. (Since the price of chemically resistance reflective foils is substantial, such approach is economically supported). The material does not interact with the reflective foil and no lamination is necessary to produce efficient devices. The presence of glycerol in the materials formula is crucial and its role (besides acting as a plasticizer) is to provide good adhesion between the device and the reflective foil which is essential for good performance of the device. The other important factor, which influences the quality of the reflective type of device is the properties of the reflective surface. The roughness of the surface should be on the order of 0.010 micrometers.

An important aspect of the material formulation is its capability to be fully polymerised at the end of the optical recording of the pattern without loss of the device's performance (Polyacrylamides are a widely-used family of polymers, whose properties are well known M. J. Caulfield, G. G. Qiao, D. H. Solomon, “Some aspects of the properties and degradation of polyacrylamides”, Chem. Rev. 102, 3067-3083 (2002)). The properties of polyacrylamides are very different to those of the monomer acrylamide from which polyacrylamide is formed. Acrylamide has been extensively studied and is shown to be both highly toxic and carcinogenic in its monomeric form. Concerns arise about residual acrylamide monomer in polyacylamide materials. Experimental conversion values of acrylamide to polyacrylamide vary greatly, from 90% to above 99.5%. This variation is due to the fact that conversion depends significantly on the reaction conditions used. There are several different techniques with which to reduce residual monomer in polyacrylamide in both aqueous and gel form. A comprehensive review of the different methods for extracting residual acrylamide is shown in Caulfield et al. These methods require additional chemicals or polymerisation catalysts, or they result in additional unwanted reactions such as gas release or corrosion, and therefore are not suitable for laminated, dry photopolymer films, as is required here.

Thermally induced polymerisation is a known technique for reducing the concentration of residual monomer, with reported conversion rates of up to 95.1% as published in M. W. C. Coville, “Treatment of acrylamide polymer gel”, U.S. Pat. No. 4,132,844 (1979); W. E. Hunter, K. A. Kun, W. B. Ramsey, “Combined visible light and thermally activated continuous polymerisation process”, U.S. Pat. No. 4,325,794A (1980); and J. D. Van Dyke, K. L. Kasperski, J. Polym. Sci. Part A: Polym. Chem. 31, 1807 (1993).

Herein is described, according to one aspect of the invention, a method to obtain full conversion of acrylamide monomer (>90%) using thermal polymerisation only, without the use of a polymerisation catalyst. A method to determine the % conversion of monomer using Raman spectroscopy is also described. The sensitized photopolymer-based optical devices are heated to temperatures in the range of 100 to 140° C. for durations longer than 60 minutes. This may be followed by UV exposure in order to further polymerise and also bleach any remaining dye in the photopolymer layer.

A custom Raman spectroscopy method has been developed in order to quantify the concentration of acrylamide monomer remaining in the polyacrylamide photopolymer layers after thermal and UV exposure. The peak at 1607 cm⁻¹ was determined by Jallapuram et al to correspond to the C═C double bond of the acrylamide monomer. By monitoring the intensity of this peak, the proportion of remaining unpolymerised AA monomer in the photopolymer layer can be quantified. A deconvolution technique must be used to distinguish between the substrate and monomer peaks. All Raman measurements are taken with an excitation wavelength of 785 nm. A 950 I/mm grating is used with a ×100 long focal length objective to allow for increased resolution and ease of focus. Lapspec v.5 software is used for all data acquisition and analysis. A BINDER (RTM) FD series heating oven is used to carry out the thermal exposure. Oven temperatures of between 100 and 140° C. are used.

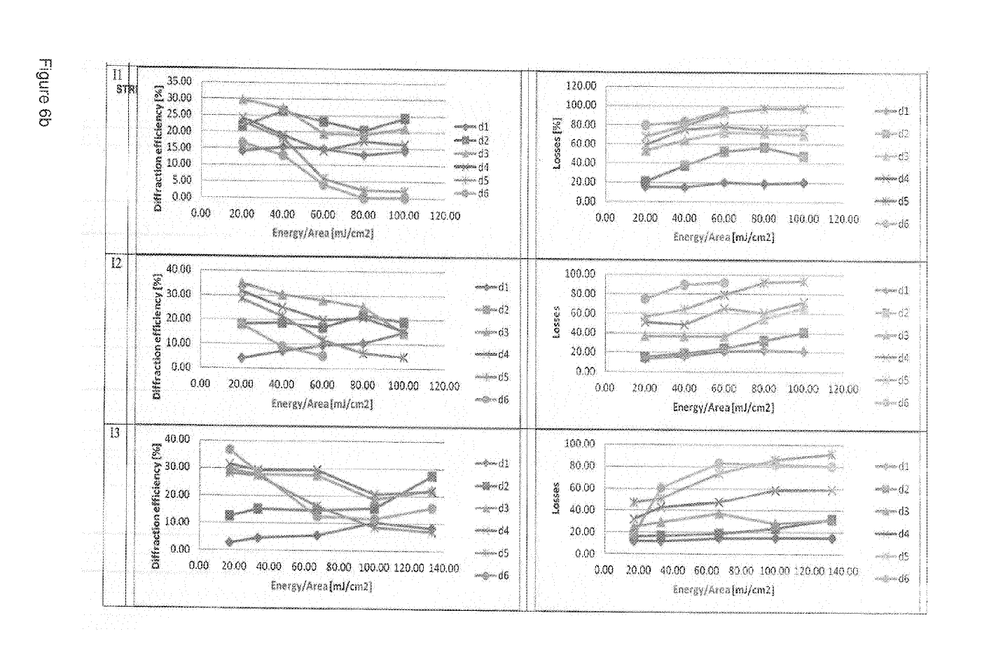

For the experimental data described herein, the photopolymer samples have been exposed to a uniform 0.5 mW/cm² beam (wavelength 532 nm) for 30 seconds to replicate device fabrication conditions. FIG. 6a shows the % remaining acrylamide monomer for the photopolymer samples after 532 nm exposure, after thermal exposure at 120° C. for 120 minutes, and after different durations of UV post-exposure with a 0.6 mW/cm² UV lamp. The % AA remaining decreases to 15±5% after thermal and UV post exposure. This post-exposure method does not damage the optical devices.

3) Experimental Condition

The experimental conditions of device production specific for the technology applied have to be optimized in order to obtain best performance of the device. As far as devices produced with SLM or contact or non-contact masking are considered, the optimisation of the experimental conditions like thickness of the layer of the photoactive material, time and intensity of exposure are necessary in order to obtain best performance of the optical devices.

For example, the results of such optimisation using six different thickness of the acrylamide-based photopolymer films and three different recording intensities I₁=0.4 mW.cm2, I₂=1 mW·cm² and I₃=1.7 mW/cm²) and varied times of recording t (for I₁ t{50, 100, 150, 200 and 250 s }, for l₂ t{20, 40, 60, 80, 100 s) and for I₃ t{10, 20, 40, 60 and 80 s}) are presented in FIG. 6b. The data were obtained for SLM recorded devices of the check patter using laminated photopolymer layers.

It can be seen from FIG. 6b that comparable and highest DE is observed for 50 and 75 μm thick devices recorded at I₁ and 75 μm thick devices recorded at I₂ and I₃. For I₁, 50 μm thick device apparently exhibits much lower losses in comparison to 75 μm devices. For 75 μm devices recorder at two different intensities, the losses are lower for I₂. The losses arise due to formation of higher orders. Although high DE could be observed for thicker films at I₃, the recording of the devices with much complex patterns did not allow generating sharp features of the projected images with these thicknesses. Summarising, best performance is observed for: 1) 50 μm thick devices recorded at 0.4 mW/cm²; further optimisation of the time of recording for 50 μm (data not showed here) revealed that the recording time can be reduced to 20-30 s 2) 75 μm devices recorded at 1 mW·cm²; recording time 20 s.

### Device Read-Out

The devices can be probed with narrow laser beam. The diameter of the beam has to be adjusted to obtain best device read-out (see effect of the probing diameter on the quality of the projected light pattern in FIG. 7)

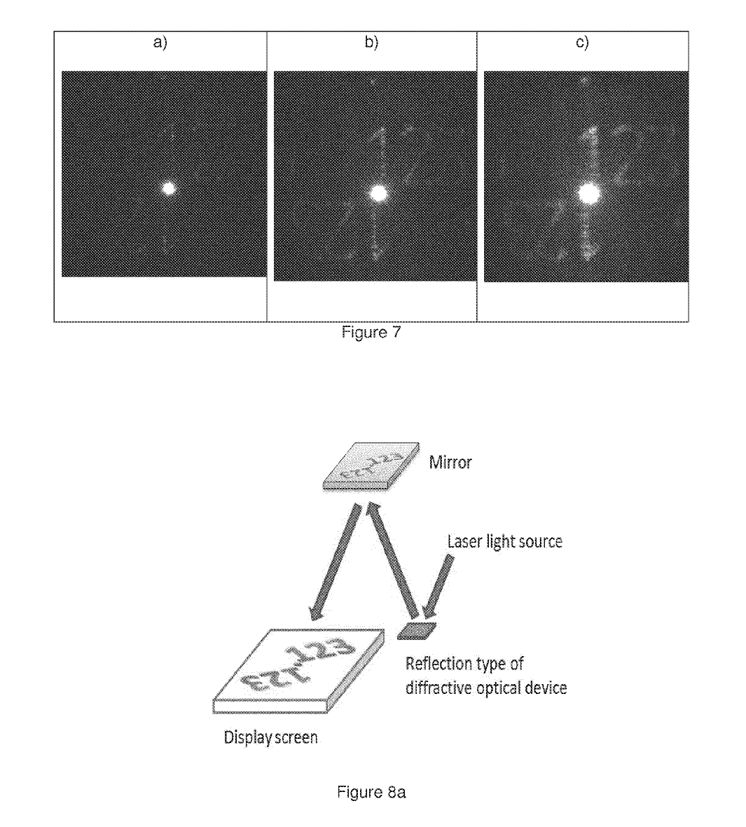

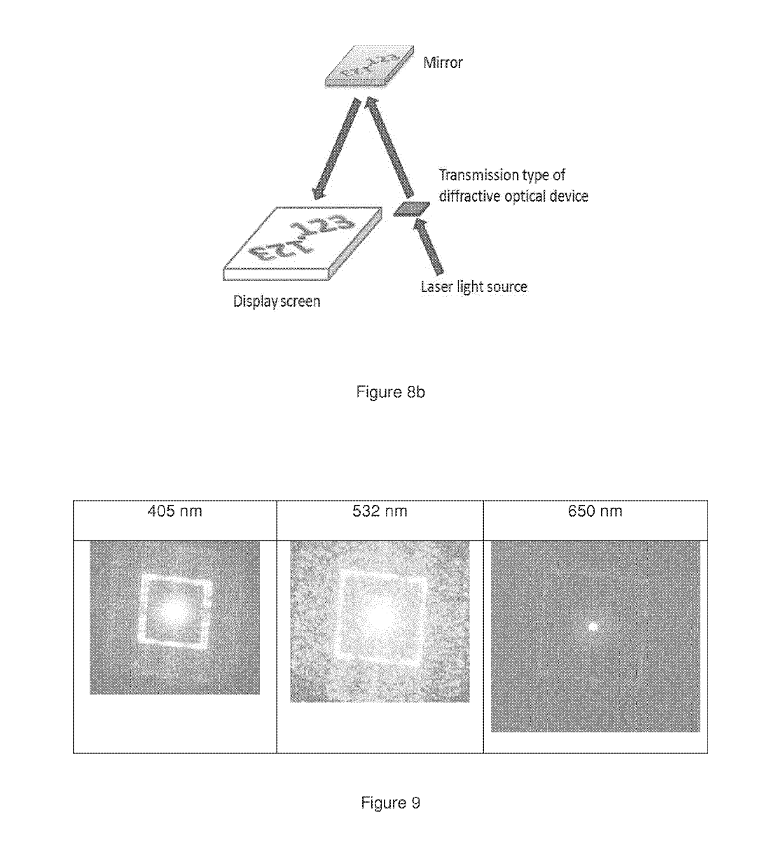

The size of the image projected through the diffractive optical element increases with distance when the device is probed with a narrow laser beam. The achievable resolution of the pattern recorded in the photoactive material limits the distance at which a recognisable image can be observed. A simple device which increases the light pathway and therefore the size of obtained light pattern, can be applied both for transmission and reflection type of the devices. A scheme of the proposed read-out devices for the reflection and transmission type of the devices is showed in FIG. 8a) and b) respectively. The optical pathway can further be extended with the use of more than one mirror /or magnifying mirror. Adjustment of the position of the mirror to reflect only the image and neither conjugate nor non-diffracted light can be carried out to improve readability of the light pattern. Probing at small angles between the probing beam and normal to the device enables to generate best quality of the projected light patterns.

To a lesser extent the size of the light pattern can be manipulated with the wavelength of the probing light (FIG. 9) which can range from visible to IR.

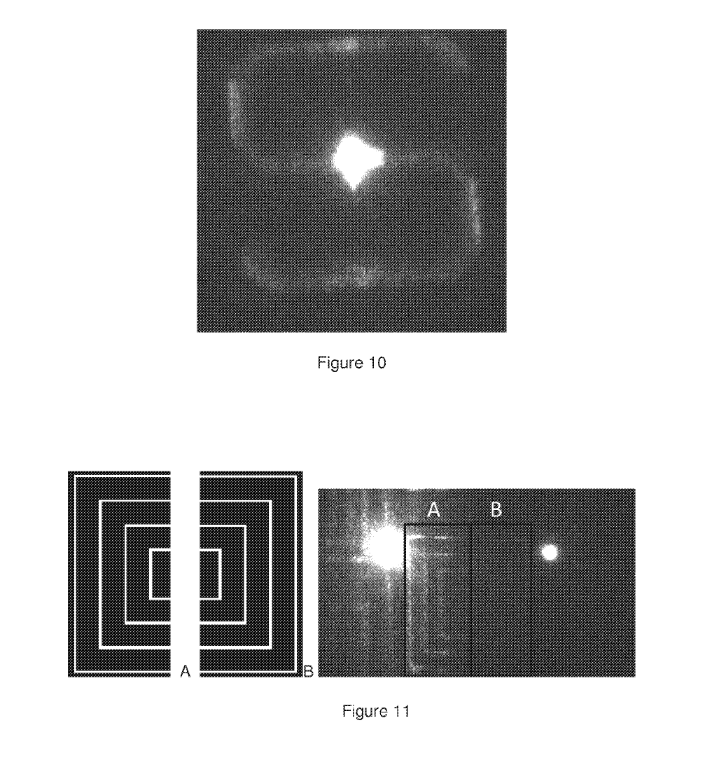

The devices, which are Fourier holograms, can be read out as such. Yet, this requires the use of a Fourier lens which makes the read-out set-up more complex. An illustration of light pattern which read-out was carried out in the focal place of the lens placed in front of the device which whole area was illuminated with collimated laser beam in showed in FIG. 10 (for comparison see image of the same device in FIG. 5 c) which was probed with narrow collimated laser beam).

### How to Increase the Information in the Projected Light Pattern

To increase the density of information that can be encoded the device can take form of a multilayer device. This embodiment imposes some challenges in reducing the scatter introduced by the boundaries between layers. This can be achieved with the help of refractive index matching material.

The limitations of the recorded patterns, in terms of the amount of data being displayed by the device, can also be overcome by merging in space patterns generated by two or more devices (see a simplified example in FIG. 11). These require the use of more than one light beam to interrogate the device (also, colourful light patterns can be generated by use of light sources of varied wavelength). Yet, for machine vision, one laser source would suffice to scan through the adjacent devices and to build up the light pattern from these devices with the help of software. Further, the device can be formed from multiple DOEs and this can increase the security of such a device. The specific DOEs can be redistributed in such a manner to hinder their read-out. Only the read-out carried out according to the predefined order and manner would allow retrieving the encrypted data. Recording multiple adjacent patterns and probing them with a scanning laser beam can be used to imitate image motion.

### Features and Benefits

Covert: The device cannot be seen under normal conditions, it requires an intense light to make the pattern visible on a surface behind the film for transmission type of the device or in front of the device for reflection type of the device.
Tamperproof: The device is fragile until protected by protective film. Attempts to tamper with or remove CODA will damage and affect the projected image.
Automatic Validation: Possibility for verification to be carried our automatically with a specially designed device.
Easy to use: The image can be displayed with a cheap laser pointer and can be seen even with large variations in incident angle of light, wavelength, intensity, or dot size.
Image Variations: Variations in the light lead to variations in the image that is displayed (e.g. colour, size, clarity). By carefully controlling the input light, these variations can be used to add additional layers of security.
Any Logo: The invention allows almost any logo or image to be created, this enhances the uniqueness of each label or tag.
Any Information: Instead of a logo a customized code can be displayed (e.g.

customized code or serial number) adding extra layers of security to the tag
Hard to copy: This technology is complex to create requiring specialized equipment and knowledge.
Invisible: The device is invisible to the eye and only reveals the pattern on the surface behind (or in front on the device for the reflection type of the device) when illuminated by a laser. It can be applied over an entire surface or just in a target location, making it easy to hide.
Applicable to all products: It can be applied in any shape or material. For the transmission type of the device it requires a transparent surface. It can be attached to products as a tag/label or integrated into packaging.

### Potential Market Benefits

Market benefits are the reduced costs, increased security, or other benefits that an end user of the invention can receive from employing the technology on their product. These benefits are determined from the key features listed above. The potential benefits of the invention are as follows:

Low cost: The technology can be manufactured as one large wafer with individual patterns being cut to form labels. This reduces the cost per label, making it a low cost technology

Individualisable: The image to be generated by a device can easily be changed with a computer.

Easy to Use: The security feature can be verified with a simple laser pointer, making this very useful for Point of Sale applications

Additional Security: The technology is covert and impossible to copy without special equipment and know how.

Tamperproof: The optical interference pattern is delicate without the protective layer.

This yields benefits as tampering with the label can be detected. The label could potentially be made to degrade under certain environmental conditions, flagging incorrect storage

The embodiments in the invention described with reference to the drawings comprise a computer apparatus and/or processes performed in a computer apparatus. However, the invention also extends to computer programs, particularly computer programs stored on or in a carrier adapted to bring the invention into practice. The program may be in the form of source code, object code, or a code intermediate source and object code, such as in partially compiled form or in any other form suitable for use in the implementation of the method according to the invention. The carrier may comprise a storage medium such as ROM, e.g. CD ROM, or magnetic recording medium, e.g. a memory stick or hard disk. The carrier may be an electrical or optical signal which may be transmitted via an electrical or an optical cable or by radio or other means.

In the specification the terms “comprise, comprises, comprised and comprising” or any variation thereof and the terms include, includes, included and including” or any variation thereof are considered to be totally interchangeable and they should all be afforded the widest possible interpretation and vice versa.

The invention is not limited to the embodiments hereinbefore described but may be varied in both construction and detail.

1. A fully transparent optical device comprising a self-processing photopolymer material patterned to diffract light from the volume of the material to generate a 2D or a 3D image when illuminated by a light source, wherein the optical device is patterned by using a single laser beam.

2. The optical device of claim 1, wherein the optical device is patterned by an in-line holographic recording of a spatially transformed wavefront.

3. The optical device of claim 1, wherein the photopolymer material comprises N-phenylglycine, NPG, glycerol triethanolamine, TEA, polyvinylalcohol, PVA, and one or more of the monomers N-isopropylacrylamide, acrylamide or diacetone acrylamide.

4. The optical device of claim 3, wherein the device is a reflection type of device.

5. The optical device of claim 3, wherein the device comprises a reflective surface placed behind a transmission type of device, wherein the reflective surface is in direct contact with the photopolymer material.

6. The optical device of claim 5, where the roughness of the reflective surface is of the order of 0.010 micrometres.

7. (canceled)

8. The optical device of claim 1, wherein the device is a transmission type of device or a reflection volume hologram device.

9. The optical device of claim 1, wherein the photopolymer material is configured by the recording of a pattern onto the photopolymer material comprising the image or a computer generated hologram of the image to be generated by the device.

10. The optical device of claim 9, wherein the computer generated hologram comprises the Fourier transform of the image to be generated by the device.

11. The optical device of claim 9, wherein the pattern is recorded by projecting light through the pattern onto the photopolymer material and the photopolymer material is sensitized to the wavelength of the light and fully or partially polymerized to form a refractive index variation in the volume of the photopolymer material.

12. The optical device of any of claim 9, wherein a single laser beam which is spatially modulated in amplitude and/or phase encrypts the recorded pattern.

13. The optical device of claim 12, wherein the pattern to be recorded onto the photopolymer material is displayed on a spatial light modulator, SLM, or incorporated into a mask or by digitally printing an ink comprising a sensitizer on the unsensitized photopolymer material.

14-16. (canceled)

17. The optical device of any of claim 1, where the image generated by the device is reflected by at least one mirror prior to read-out.

18-20. (canceled)

21. A method of producing a diffractive optical element, DOE, from an optical device comprising a photopolymer material, the method comprising:
optically recording a pattern in the photopolymer material by projecting a single beam of laser light through the pattern onto the photopolymer material so as to cause a refractive index variation in the volume of the photopolymer material, wherein the material is fully or partially polymerized at the end of the optical recording.

22. (canceled)

23. The method of claim 21, wherein the step of projecting light through the pattern comprises projecting light through a pattern displayed on an SLM or through a pattern on a physical mask.

24.-25. (canceled)

26. The method of claim 21, further comprising digitally printing a computer generated pattern using ink comprising a sensitizer on the unsensitized photopolymer material prior to recording.

27. The method of claim 21, further comprising heating the optical device to a temperature in the range 100 to 140 degrees Celsius for a period greater than 60 minutes to fully polymerize and/or improve the characteristics of the device.

28. The method of claim 27, further comprising exposing the optical device to ultra violet, UV, light. 29-30. (canceled)

31. The method of claim 21, wherein the thickness of the photopolymer material is between 20-150 μm and recording intensity and time of recording are in the range 0.4-2 mW/cm2 and 10-80 s respectively.

32. (canceled)

33. An optical device comprising a plurality of DOEs, each formed from the method of claim 21, wherein each DOE is distributed in a predefined manner or is multiplexed in the same location.

34-39. (canceled)
